(19) United States
(12) Patent Application Publication
(10) Pub. No.: US 2025/0274030 A1
(43) Pub. Date: Aug. 28, 2025

(54) Power Conversion System and Cooling Apparatus

(71) Applicant: AA Power Inc., Boston, MA (US)

(72) Inventor: Qun Lu, Lexington, MA (US)

(21) Appl. No.: 19/057,935

(22) Filed: Feb. 19, 2025

Related U.S. Application Data
(60) Provisional application No. 63/557,333, filed on Feb. 23, 2024.

(51) Int. Cl. H02M 1/00; H02M 1/32; H02M 1/42; H02M 3/00; H02M 3/335; H02M 7/10; H02M 7/25

(52) U.S. Cl. CPC H02M 1/007; H02M 1/327; H02M 1/4266; H02M 1/4291; H02M 3/003; H02M 3/01; H02M 3/33592; H02M 7/10; H02M 7/25

(57) ABSTRACT

A system comprises a first power stage and a second power stage coupled in cascade between an ac source and a load, a high voltage bus connected between the first power stage and the second power stage, a first cooling apparatus configured to cool the first power stage, and a second cooling apparatus configured to cool the second power stage, wherein the high voltage bus passes through a wall of the second cooling apparatus.

### PRIORITY

This application claims the benefit of U.S. Provisional Application No. 63/557,333, filed on Feb. 23, 2024, entitled “Power Conversion System and Cooling Apparatus,” which application is hereby incorporated herein by reference.

### TECHNICAL FIELD

The present invention relates to a power conversion system and the associated cooling apparatus, and, in particular embodiments, to a power conversion system including at least two power stages connected in cascade and a hybrid cooling system for cooling different stages of the power conversion system.

### BACKGROUND

As technologies continue to advance, high-performance computing applications have grown increasingly demanding. One such application is the use of graphics processing units (GPUs) in data centers for artificial intelligence (AI), machine learning, high-performance computing (HPC), and gaming. These GPU-based systems require substantial power to operate efficiently. In large-scale deployments, such as data centers and cloud computing facilities, numerous GPUs are installed to perform intensive computational tasks. Each GPU operates as part of a broader computing system, drawing significant power and generating substantial heat during operation.

In a GPU-based computing system, each GPU is powered by a dedicated power conversion system. This power conversion system is connected between the electric grid and the GPUs, converting the ac voltage of the grid into a suitable dc voltage required for GPU operation. Traditionally, power conversion systems have utilized a 48V voltage bus to supply power. However, as power demands continue to escalate, the 48V bus has proven insufficient for efficiently delivering high power levels. Higher voltage bus architectures are being explored to enhance power delivery efficiency, minimize losses, and reduce overall system costs.

During operation, the power conversion system generates excess heat, which must be effectively managed to ensure reliable performance. Typically, this heat is dissipated into the surrounding environment until thermal equilibrium is reached. However, under certain high-power conditions, conventional heat dissipation methods fail to adequately manage the thermal load, leading to excessive operating temperatures. Elevated temperatures accelerate component degradation and reduce the lifespan of the power conversion system. To address this issue, liquid cooling techniques have been introduced to improve thermal management. However, traditional immersion cooling fluids can be highly corrosive and pose durability challenges for power supply components. Exposure to these coolants can accelerate degradation, shortening the operational lifespan of the power conversion system. Additionally, when power conversion units are enclosed within sealed cooling enclosures, accessing and servicing failed components becomes complex and time-consuming. The present disclosure addresses these challenges by providing an improved power conversion system for GPU-based applications.

### SUMMARY

These and other problems are generally solved or circumvented, and technical advantages are generally achieved, by preferred embodiments of the present disclosure which provide a power conversion system including at least two power stages connected in cascade and a hybrid cooling system for cooling different stages of the power conversion system.

In accordance with an embodiment, a system comprises a first power stage and a second power stage coupled in cascade between an ac source and a load, a high voltage bus connected between the first power stage and the second power stage, a first cooling apparatus configured to cool the first power stage, and a second cooling apparatus configured to cool the second power stage, wherein the high voltage bus passes through a wall of the second cooling apparatus.

In accordance with another embodiment, a method comprises providing a power conversion system comprising a first power stage and a second power stage connected in cascade, wherein a high voltage bus is connected between the first power stage and the second power stage, and configuring a first cooling system to cool the first power stage and a second cooling system to cool the second power stage, wherein the high voltage bus passes through a wall of the second cooling system.

In accordance with yet another embodiment, a system comprises a plurality of first power stages coupled between an ac source and a high voltage bus, a plurality of second power stages coupled between the high voltage bus and a load, a first cooling apparatus configured to cool the plurality of first power stages, and a second cooling apparatus configured to cool the plurality of second power stages and the load, wherein the high voltage bus passes through a wall of the second cooling apparatus.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a power conversion system comprising a first power stage and a second power stage connected in cascade between a three-phase ac source and a load in accordance with various embodiments of the present disclosure;

FIG. 2 illustrates a block diagram of a power conversion system comprising a first power stage, a second power stage and a third power stage connected in cascade between a three-phase ac source and a load in accordance with various embodiments of the present disclosure;

FIG. 3 illustrates a schematic diagram of the first power stage shown in FIG. 1 in accordance with various embodiments of the present disclosure;

FIG. 4 illustrates a schematic diagram of the second power stage shown in FIG. 1 in accordance with various embodiments of the present disclosure;

FIG. 5 illustrates a block diagram of a power conversion system comprising a plurality of first power stages connected between a three-phase ac source and a high voltage bus, and a plurality of second power stages connected between the high voltage bus and a load in accordance with various embodiments of the present disclosure;

FIG. 6 illustrates a perspective view of a power supply unit in accordance with various embodiments of the present disclosure;

FIG. 7 illustrates an exploded view of the interior of the power supply unit shown in FIG. 6 in accordance with various embodiments of the present disclosure;

FIG. 8 illustrates a perspective view of the housing in accordance with various embodiments of the present disclosure;

FIG. 9 illustrates another configuration of the liquid inlet and outlet in accordance with various embodiments of the present disclosure;

FIG. 10 illustrates a first cooling implementation of the housing in accordance with various embodiments of the present disclosure;

FIG. 11 illustrates a second cooling implementation of the housing in accordance with various embodiments of the present disclosure;

FIG. 12 illustrates a third cooling implementation of the housing in accordance with various embodiments of the present disclosure;

FIG. 13 illustrates a fourth cooling implementation of the housing in accordance with various embodiments of the present disclosure;

FIG. 14 illustrates a fifth cooling implementation of the housing in accordance with various embodiments of the present disclosure;

FIG. 15 illustrates a sixth cooling implementation of the housing in accordance with various embodiments of the present disclosure;

FIG. 16 illustrates a seventh cooling implementation of the housing in accordance with various embodiments of the present disclosure;

FIG. 17 illustrates an eighth cooling implementation of the housing in accordance with various embodiments of the present disclosure;

FIG. 18 illustrates a ninth cooling implementation of the housing in accordance with various embodiments of the present disclosure;

FIG. 19 illustrates a perspective view of another implementation of the power supply unit in accordance with various embodiments of the present disclosure;

FIG. 20 illustrates a left-side view, a top side view, a right-side view and a bottom side view of the power supply unit shown in FIG. 19 in accordance with various embodiments of the present disclosure; and

FIG. 21 illustrates a flow chart of a method for cooling the power conversion system shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely a power conversion system including at least two power stages connected in cascade and a hybrid cooling system for cooling different stages of the power conversion system. The disclosure may also be applied, however, to a variety of power conversion systems. Hereinafter, various embodiments will be explained in detail with reference to the accompanying drawings.

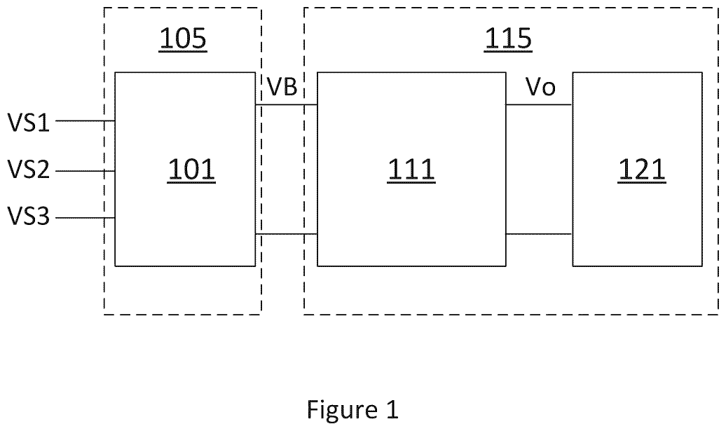

FIG. 1 illustrates a block diagram of a power conversion system comprising a first power stage and a second power stage connected in cascade between a three-phase ac source and a load in accordance with various embodiments of the present disclosure. As shown in FIG. 1, a first power stage 101 and a second power stage 111 are coupled in cascade between an ac source and a load 121.

The ac source is a three-phase ac source comprising a first phase VS1, a second phase VS2 and a third phase VS3. A high voltage bus VB is connected between the first power stage 101 and the second power stage 111. In some embodiments, a voltage on the high voltage bus is in a range from about 360 V to about 400 V.

In a conventional power conversion system, the first power stage 101 is coupled to a single-phase ac source. Balancing the phases of the ac input becomes necessary. In other words, when a single-phase ac source is used, there is a necessity to balance three-phase power to minimize power loss on the neutral line. Furthermore, due to the phase difference, it is hard to configure a plurality of first power stages connected in parallel when the first power stages are connected to single-phase ac sources. In the power conversion system shown in FIG. 1, since the three-phase ac source has three sine waves that are 1200 off from one another, the ripple from the three-phase ac source is less than that of a single-phase ac source.

In some embodiments, the first power stage 101 is cooled by a first cooling apparatus 105. In particular, the first cooling apparatus 105 is configured to utilize air to dissipate heat generated by the first power stage 101. The second power stage 111 is placed in a second cooling apparatus 115. The second cooling apparatus 115 comprises a tank configured to hold a coolant. The second cooling apparatus 115 is configured to utilize liquid to dissipate heat. The second power stage 111 is sealed inside the tank. The second cooling apparatus 115 is configured to cool the second power stage 111. As indicated by FIG. 1, the high voltage bus VB passes through a wall of the second cooling apparatus 115. In some embodiments, a cooling capacity of the second cooling apparatus 115 is greater than a cooling capacity of the first cooling apparatus 105. In alternative embodiments, the second cooling apparatus 115 comprises a plurality of liquid pipes supplied coolant to the second power stage 111.

In some embodiments, the loads (e.g., load 121) comprise a plurality of graphics processing units (GPUs), a plurality of application-specific integrated chips (ASICs), any combinations thereof and the like.

In some embodiments, the first power stage 101 is a three-phase buck-type power factor correction rectifier. The three-phase buck-type power factor correction rectifier is packaged in one module. The three-phase buck-type power factor correction rectifier is configured to convert the three-phase ac source into a dc voltage in a range from about 360 V to about 400 V on the high voltage bus VB. In alternative embodiments, depending on different applications and design needs, the first power stage 101 may be implemented as a boost converter. Furthermore, the first power stage 101 may be an isolated power converter with a forward topology, a fly-forward topology, a flyback topology, any combinations thereof and the like. In some applications, the integrated magnetics technology is used to design the first power stage 101. More particularly, magnetic components such as inductors, transformers, or other passive magnetic devices are combined together on a printed circuit board (PCB). For example, the functions of transformers and inductors can be combined into a single device, thereby achieving space savings, reduced weight, and possibly improved efficiency compared to using separate components. The integrated magnetic components offer a variety of advantages such as reduced size, weight, and cost, as well as improved performance due to reduced parasitic effects and better control over the magnetic field.

In some embodiments, the second power stage 111 is an inductor-inductor-capacitor (LLC) resonant converter. The LLC resonant converter offers two power conversion approaches. In a first approach, the LLC resonant converter directly converts the voltage on the high voltage bus VB (e.g., 380 V) to a lower voltage (e.g., 20 V). In a second approach, the LLC resonant converter directly converts the voltage on the high voltage bus VB (e.g., 380 V) to a lower bus voltage (e.g., 48 V or 12 V), and subsequently distributes power to GPUs or ASICs via point-of-load dc/dc power converters.

In alternative embodiments, depending on different applications and design needs, the second power stage 111 may be implemented as an isolated power converter such as a forward converter, a flying converter, a fly-forward converter, a full bridge converter, a half bridge converter, any combinations thereof and the like.

In operation, the first power stage 101 is a three-phase buck-type power factor correction rectifier. The second power stage 111 is an LLC resonant converter. The three-phase buck-type power factor correction rectifier is controlled such that the LLC resonant converter is configured to operate at a predetermined duty cycle.

In operation, the first power stage 101 is a three-phase buck-type power factor correction rectifier. The second power stage 111 is an LLC resonant converter. The three-phase buck-type power factor correction rectifier is controlled such that the LLC resonant converter is configured to operate at a predetermined switching frequency.

In operation, the three-phase buck-type power factor correction rectifier is configured to operate in three different operating modes. In a linear mode, at least one power switch of the three-phase buck-type power factor correction rectifier is driven by an adjustable gate drive voltage so that an output voltage of the three-phase buck-type power factor correction rectifier is adjusted. In a PWM mode, a duty cycle of the three-phase buck-type power factor correction rectifier is adjusted so that the output voltage of the three-phase buck-type power factor correction rectifier is adjusted. In a hybrid mode, the linear mode and the PWM mode are applied to the three-phase buck-type power factor correction rectifier in an alternating manner so that the output voltage of the three-phase buck-type power factor correction rectifier is adjusted and thermal stress is alleviated.

In operation, a first system controller (not shown) is configured to determine the operation of the first power stage 101. A second system controller (not shown) is configured to determine the operation of the second power stage 111. In particular, based on a variety of operating parameters, the first system controller is configured to generate gate drive signals for the first power stage 101. Likewise, the second system controller is configured to generate gate drive signals for the second power stage 111.

In the power conversion system shown in FIG. 1, a three-phase power factor correction (PFC) circuit (e.g., the first power stage 101) is employed to equalize three-phase power consumption, thereby mitigating losses in power transmission. The three-phase PFC circuit is a buck-type power factor correction rectifier. This buck-type power factor correction rectifier is configured to generate a voltage in a range from about 360 V to about 400 V on the high voltage bus VB. Such a voltage efficiently interfaces with the existing ac/dc power architecture in computing systems. Furthermore, this voltage level facilitates a seamless voltage conversion using widely available components.

In some embodiments, the second cooling apparatus 115 is a liquid-cooled sealed enclosure (e.g., a sealed tank) possessing strong corrosive properties. The ac/dc power converter (e.g., the first power stage 101) has susceptible components (e.g., electrolytic capacitors) with an estimated lifespan in a range from 3 years to 7 years. The high-performance computing liquid cooling system has an estimated lifespan in a range from 5 years to 10 years. If the ac/dc power converter (e.g., the first power stage 101) is placed inside the liquid-cooled sealed enclosure, the likelihood of needing to open the sealed liquid cooling enclosure to replace a faulty unit during operation is increased.

In some applications, the first power stage 101 may contain numerous vulnerable components such as electrolytic capacitors, transformers, and wire-wound inductors. These components are susceptible to short lifespans. In contrast, the second power stage 111 is a dc/dc converter. The dc/dc converter lacks components with low lifespans and exhibits good corrosion resistance.

As shown in FIG. 1, the first power stage 101 is placed outside the liquid-cooled sealed enclosure. The liquid-cooled sealed enclosure is used to house the second power stage 111. Given the absence of components with short lifespans and its strong resistance to corrosion, the second power stage 111 is less likely to require opening the sealed liquid cooling enclosure for unit replacement during operation. Furthermore, the first power stage 101 is a high efficiency PFC section. The heat generated by the first power stage 101 can be dissipated by air. Moreover, since the first power stage 101 is placed outside the liquid-cooled sealed enclosure, replacement becomes feasible when necessary.

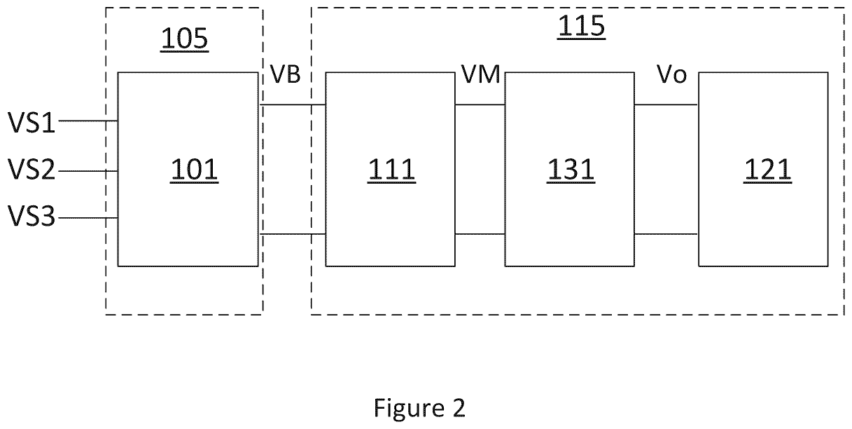

FIG. 2 illustrates a block diagram of a power conversion system comprising a first power stage, a second power stage and a third power stage connected in cascade between a three-phase ac source and a load in accordance with various embodiments of the present disclosure. The power conversion system shown in FIG. 2 is similar to that shown in FIG. 1 except that a third power stage 131 is connected between the second power stage 111 and the load 121. In some embodiments, the third power stage 131 is a non-isolated step-down dc/dc converter. Alternatively, the third power stage 131 may be implemented as any suitable non-isolated dc/dc converters such as a buck converter, a boost converter, a buck-boost converter, any combinations thereof and the like.

In operation, the second power stage 111 is configured to convert the voltage on the high voltage bus VB (e.g., 380 V) to a lower bus voltage (e.g., 48 V or 12 V). The third power stage 131 is configured to convert the voltage on the lower bus to a voltage (e.g., 0.8 V) suitable for powering GPUs or ASICs.

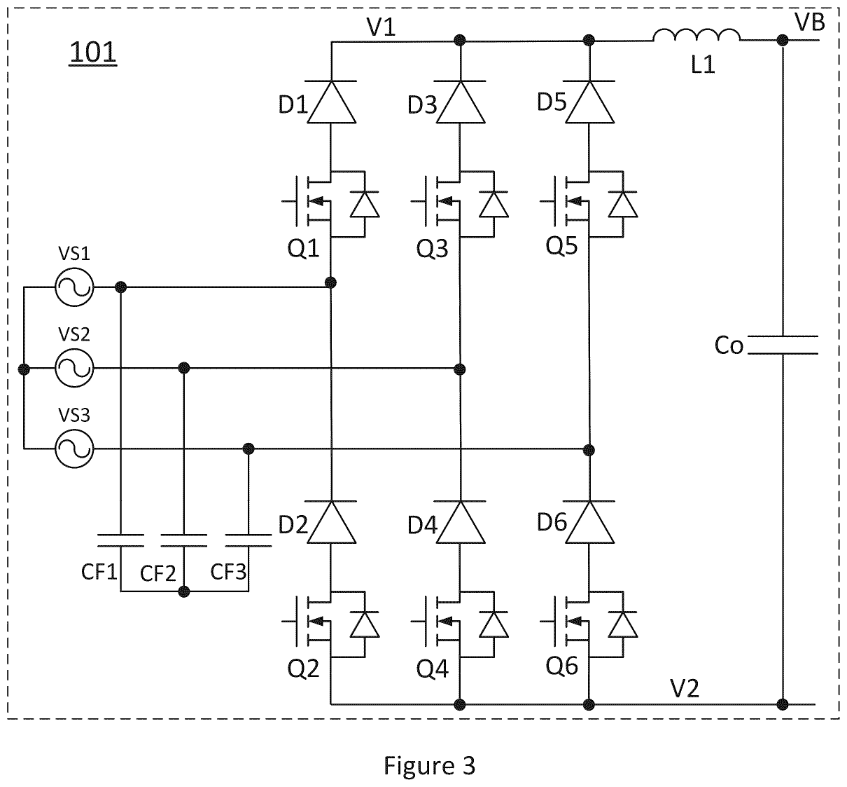

FIG. 3 illustrates a schematic diagram of the first power stage shown in FIG. 1 in accordance with various embodiments of the present disclosure. The first power stage 101 is implemented as a three-phase buck-type power factor correction rectifier. As shown in FIG. 3, the three-phase buck-type power factor correction rectifier comprises three filter capacitors, three switch legs, an inductor L1 and an output capacitor Co.

As shown in FIG. 3, a first filter capacitor CF1 is connected between an output of a first phase VS1 of the three-phase ac source and a neutral point. A second filter capacitor CF2 is connected between an output of a second phase VS2 of the three-phase ac source and the neutral point. A third filter capacitor CF3 is connected between an output of a third phase VS3 of the three-phase ac source and the neutral point.

A first leg comprises a first diode D1, a first power switch Q1, a second diode D2 and a second power switch Q2. The first diode D1, the first power switch Q1, the second diode D2 and the second power switch Q2 are connected in series between a first voltage bus V1 and a second voltage bus V2. A common node of the first power switch Q1 and the second diode D2 is connected to the first phase VS1 of the three-phase ac source as shown in FIG. 3.

A second leg comprises a third diode D3, a third power switch Q3, a fourth diode D4 and a fourth power switch Q4. The third diode D3, the third power switch Q3, the fourth diode D4 and the fourth power switch Q4 are connected in series between the first voltage bus V1 and the second voltage bus V2. A common node of the third power switch Q3 and the fourth diode D4 is connected to the second phase VS2 of the three-phase ac source ac source as shown in FIG. 3.

A third leg comprises a fifth diode D5, a fifth power switch Q5, a sixth diode D6 and a sixth power switch Q6. The fifth diode D5, the fifth power switch Q5, the sixth diode D6 and the sixth power switch Q6 are connected in series between the first voltage bus V1 and the second voltage bus V2. A common node of the fifth power switch Q5 and the sixth diode D6 is connected to the third phase VS3 of the three-phase ac source ac source as shown in FIG. 3.

The inductor L1 is connected between the first voltage bus V1 and the high voltage bus VB. The output capacitor Co is connected between the high voltage bus VB and the second voltage bus V2. In some embodiments, the output capacitor Co comprises an electrolytic capacitor. In alternative embodiments, the output capacitor Co comprises a plurality of electrolytic capacitors connected in parallel.

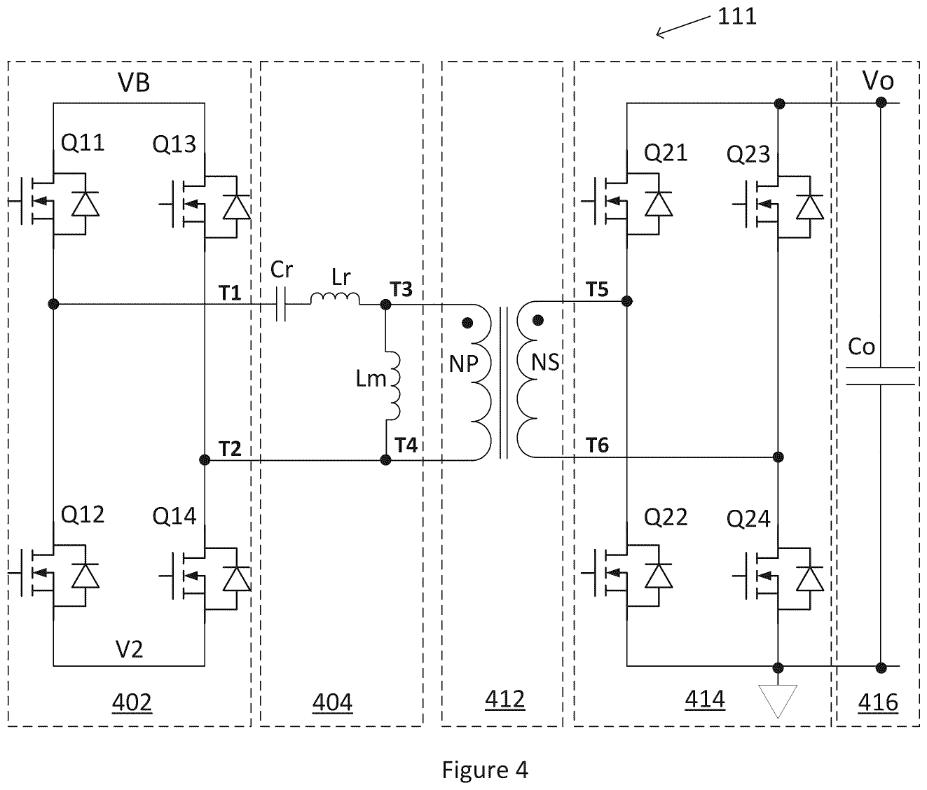

FIG. 4 illustrates a schematic diagram of the second power stage shown in FIG. 1 in accordance with various embodiments of the present disclosure. The second power stage 111 is implemented as an LLC resonant converter. As shown in FIG. 4, the LLC resonant converter comprises a switch network 402, a resonant tank 404, a transformer 412, a rectifier 414 and an output filter 416. As shown in FIG. 4, the switch network 402, the resonant tank 404, the transformer 412, the rectifier 414 and the output filter 416 are coupled to each other and connected in cascade between the high voltage bus VB and a load (not shown) coupled to the output of the LLC resonant converter.

The switch network 402 includes four switching elements, namely Q11, Q12, Q13 and Q14. Throughout the description, the switch network 402 is alternatively referred to as a primary switch network.

As shown in FIG. 4, a first pair of switching elements Q11 and Q12 are connected in series between the high voltage bus VB and the second voltage bus V2. A second pair of switching elements Q13 and Q14 are connected in series between the high voltage bus VB and the second voltage bus V2. The common node of the switching elements Qi1 and Q12 is coupled to a first input terminal T1 of the resonant tank 404. Likewise, the common node of the switching elements Q13 and Q14 is coupled to a second input terminal T2 of the resonant tank 404.

FIG. 4 further illustrates the resonant tank 404 is coupled between the switch network 402 and the transformer 412. The resonant tank 404 is formed by a series resonant inductor Lr, a series resonant capacitor Cr and a parallel inductance Lm. As shown in FIG. 4, the series resonant inductor Lr and the series resonant capacitor Cr are connected in series and further coupled to the primary side of the transformer 412.

It should be noted while FIG. 4 shows the series resonant inductor Lr is an independent component, the series resonant inductor Lr may be replaced by the leakage inductance of the transformer 412. In other words, the leakage inductance (not shown) may function as the series resonant inductor Lr.

It should further be noted while FIG. 4 shows the resonant tank is placed on the primary side of the LLC resonant converter, this diagram is merely an example. A person skilled in the art will recognize many variations, alternatives and modifications. For example, the resonant tank may be placed on the secondary side. Furthermore, the resonant tank may be placed on both sides of the transformer 412.

The transformer 412 has a primary winding NP and a secondary winding NS. The primary winding is coupled to terminals T3 and T4 of the resonant tank 404 as shown in FIG. 4. The secondary winding is coupled to the output of the LLC resonant converter through the rectifier 414, which is a full-bridge rectifier comprising switches Q21, Q22, Q23 and Q24. Throughout the description, the rectifier 414 is alternatively referred to as a secondary switch network.

As shown in FIG. 4, switches Q21 and Q22 are connected in series and further coupled between two terminals of the output capacitor Co. Switches Q23 and Q24 are connected in series and further coupled between the two terminals of the output capacitor Co. The common node T5 of the switches Q21 and Q22 is coupled to a first terminal of the secondary winding of the transformer 412. Likewise, the common node T6 of the switches Q23 and Q24 is coupled to a second terminal of the secondary winding of the transformer 412.

It should be noted that the transformer structure shown in FIG. 4 is merely an example. One person skilled in the art will recognize many alternatives, variations and modification. For example, the secondary side of the transformer 412 may be a center tapped transformer winding. As a result, the secondary side may employ a synchronous rectifier formed by two switching elements. The operation principle of a synchronous rectifier coupled to a center tapped transformer winding is well known, and hence is not discussed in further detail herein to avoid repetition.

It should further be noted that the power topology of the LLC resonant converter may be not only applied to the rectifier as shown in FIG. 4, but also applied to other secondary configurations, such as voltage doubler rectifiers, current doubler rectifiers, any combinations thereof and/or the like.

In operation, when the switching frequency of the LLC resonant converter is equal to the resonant frequency of the resonant tank of the LLC resonant converter, the LLC resonant converter may have a unity system gain. On the other hand, when the switching frequency of the LLC resonant converter is higher than the resonant frequency, the LLC resonant converter is of a lower system gain.

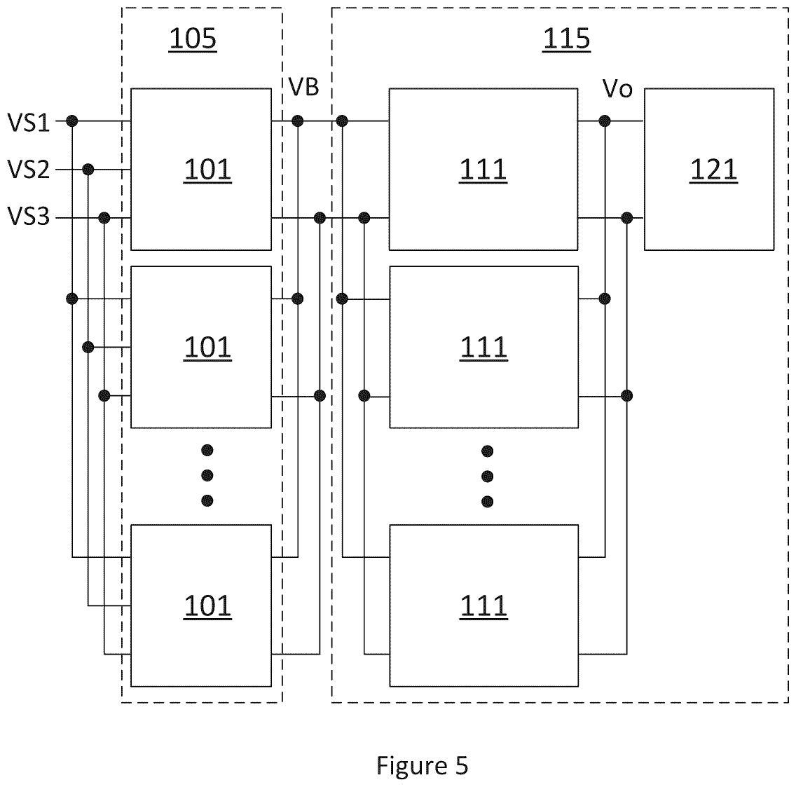

FIG. 5 illustrates a block diagram of a power conversion system comprising a plurality of first power stages connected between a three-phase ac source and a high voltage bus, and a plurality of second power stages connected between the high voltage bus and a load in accordance with various embodiments of the present disclosure. As shown in FIG. 5, a plurality of first power stages 101 is coupled between an ac source and a high voltage bus VB. The ac source is a three-phase ac source. A plurality of second power stages 111 is coupled between the high voltage bus VB and a load 121. In some embodiments, the load comprises a plurality of processors such as GPU processors. A first cooling apparatus 105 is configured to cool the plurality of first power stages 101. A second cooling apparatus 115 is configured to cool the plurality of second power stages 111 and the load 121. The high voltage bus VB passes through a wall of the second cooling apparatus 115.

In some embodiments, the first cooling apparatus 105 is configured to cool the plurality of first power stages 101. In particular, the first cooling apparatus 105 is configured to utilize air to dissipate heat generated by the plurality of first power stages 101. In some embodiments, the second cooling apparatus 115 comprises a tank configured to hold a coolant. The second cooling apparatus 115 is configured to utilize liquid to dissipate heat generated by the plurality of second power stages 111. In alternative embodiments, the second cooling apparatus 115 comprises a plurality of liquid pipes supplied coolant to the plurality of second power stages 111, thereby dissipating the heat generated by the plurality of second power stages 111.

In some embodiments, each first power stage 101 is a three-phase buck-type power factor correction rectifier. The three-phase buck-type power factor correction rectifier is configured to convert the three-phase ac source into a dc voltage in a range from about 360 V to about 400 V on the high voltage bus VB. Each second power stage 111 is an LLC resonant converter.

In some embodiments, the plurality of first power stages 101 is connected in parallel and hot swappable. A cardinality of the plurality of first power stages 101 is greater than a cardinality of the plurality of second power stages 111. For example, the power conversion system may comprise 17 second power stages 111 and 20 first power stages 101. Each power stage has a power rating of about 30 kilowatts.

In some embodiments, the second power stages 111 are implemented as a plurality of power supply units. The power supply unit is typically a rectangular, metal-encased module designed to fit within server racks or dedicated power supply unit slots. One panel (front panel or rear panel) of the power supply unit often comprises input and output connectors (input and output interfaces). The connectors include ports for ac or dc input, depending on the power configuration of the data center, and multiple output connections that link to power distribution units or directly to server components.

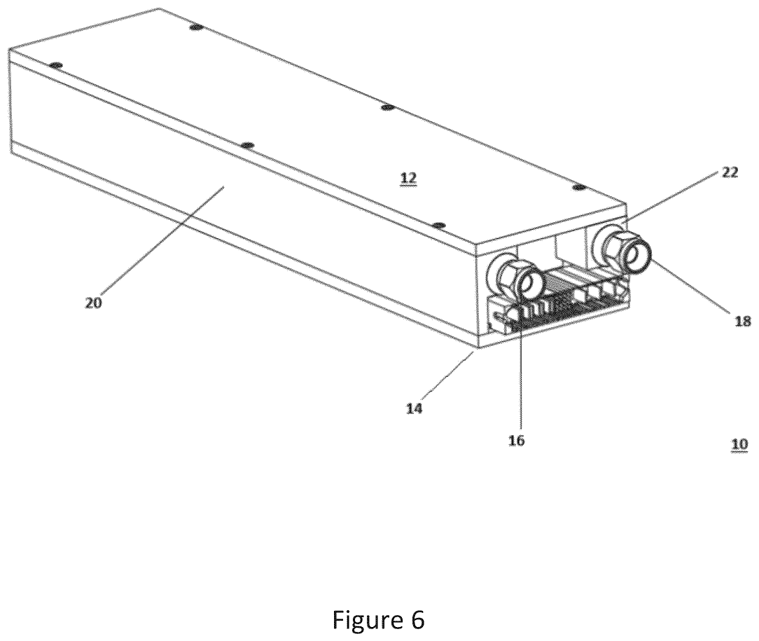

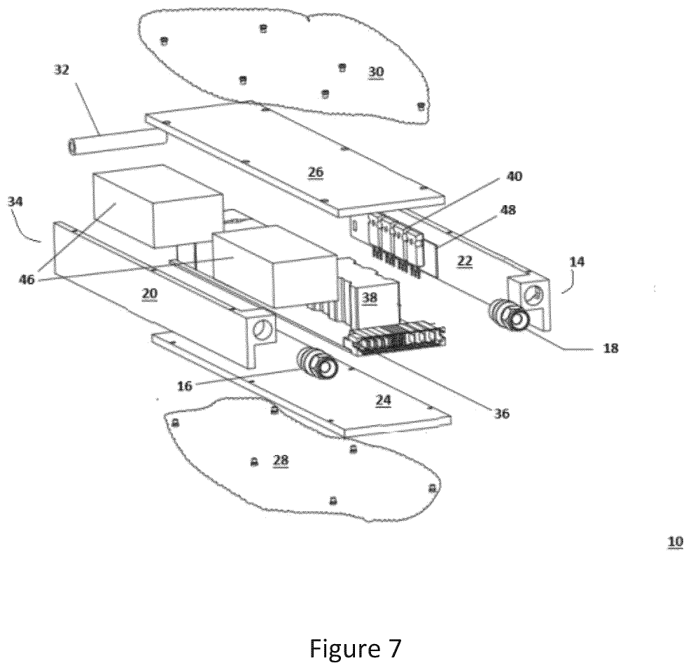

FIG. 6 illustrates a perspective view of a power supply unit in accordance with various embodiments of the present disclosure. The power supply unit 10 includes a housing 12. The housing 12 comprises a first sidewall portion 20, a second sidewall portion 22, a bottom case portion 24 (shown in FIG. 7), a top case portion 26 (shown in FIG. 7), a front end 34 (shown in FIG. 7) and a rear end 14. As shown in FIG. 6, the first sidewall portion 20 extends longitudinally from the rear end 14 to the front end. Likewise, the second sidewall portion 22 extends longitudinally from the rear end 14 to the front end.

At the rear end 14, there is a housing inlet 16 for cooling fluid to enter and a housing outlet 18 for the cooling fluid to exit after absorbing heat generated within the housing 12. An external pump supplies the energy necessary to drive the fluid flow from the housing inlet 16, through the housing 12, and out the housing outlet 18. In some embodiments, the housing inlet 16 and outlet 18 are connected to the first sidewall portion 20 and the second sidewall portion 22, respectively, allowing fluid flow between them. As a result of connecting the housing inlet 16 and outlet 18 to the sidewall portions, the first sidewall portion 20 functions as a first cold plate, and the second sidewall portion 22 functions as a second cold plate. The two cold plates are used to form a liquid-cooled power supply.

The power supply unit 10 handles high levels of electrical current through connectors located at the rear end 14. These electrical connectors contain conductors that carry current, which results in ohmic heating as current flows through them. The heating is influenced by the current density, or the amount of current passing through a given area of the conductor. Since ohmic heating is directly related to current density, larger connectors are beneficial as they reduce current density by distributing the current over a larger surface area. This, in turn, minimizes heating and reduces ohmic losses.

The use of these larger connectors requires significant space at the rear end 14. In traditional air-cooled power supplies, much of this space is occupied by air vents, limiting the size of the connectors. However, since the power supply unit 10 shown in FIG. 6 is liquid-cooled, the need for bulky air vents is eliminated, freeing up space for larger connectors. Additionally, to further optimize space, the housing inlet 16 and outlet 18 are positioned at the corners of the rear end 14, increasing the available contiguous area and allowing for even larger connectors, thereby reducing ohmic heating losses.

FIG. 7 illustrates an exploded view of the interior of the power supply unit shown in FIG. 6 in accordance with various embodiments of the present disclosure. As shown in FIG. 7, the first sidewall portion 20 and the second sidewall portion 22 are secured to the bottom case portion 24 and the top case portion 26 using corresponding floor screws 28 and ceiling screws 30. A connecting channel 32 runs transversely at the front end 34 of the housing 12.

A printed-circuit board assembly 36 is placed inside the housing 12. The printed-circuit board assembly 36 supports various components that require cooling. These components include magnetic components, capacitors and semiconductor components. Another component requiring cooling is a heat sink mounted on the printed-circuit board assembly 36. These components are thermally connected to either the first sidewall portion 20 or the second sidewall portion 22.

In some embodiments, modules 46 comprise heat-generation components including magnetic components (e.g., power transformer and/or inductor), semiconductor switches (e.g., power switches) and capacitors. These heat-generation components are rectangular modules designed to fit within the housing 12. The rectangular module 46 has a first sidewall, a second sidewall, a bottom portion, a top portion, a front end and a rear end. In order to better dissipate heat, at least one side of the rectangular module 46 is in direct contact with the cold plate of the housing 12.

In a first configuration of the rectangular module 46 and the housing 12, one sidewall of the rectangular module 46 is formed of thermally conductive materials. The one sidewall of the rectangular module 46 is in direct contact with the sidewall portion of the housing 12. This arrangement enables efficient heat dissipation from the rectangular module 46 through the sidewall portion, which is liquid-cooled by a suitable coolant.

In a second configuration of the rectangular module 46 and the housing 12, two sidewalls of the rectangular module 46 are formed of thermally conductive materials. The two sidewalls of the rectangular module 46 are in direct contact with the two sidewall portions of the housing 12, respectively. In some embodiments, the rectangular module 46 is a transformer. The sidewalls of the rectangular module 46 are occupied by the windings of the transformer. The windings on the sidewalls of the rectangular module 46 are in direct contact with the two sidewall portions of the housing 12, respectively. Alternatively, the sidewalls of the rectangular module 46 are occupied by different portions of the magnetic core of the transformer. The different portions of the magnetic core are in direct contact with the two sidewall portions of the housing 12, respectively. This arrangement enables efficient heat dissipation from the transformer through the sidewall portions, which are liquid-cooled by a suitable coolant.

It should be noted that in order to insulate the winding of the transformer and the sidewall of the housing 12, a suitable dielectric layer may be formed on the sidewall of the housing 12, the winding of the transformer, or both.

In a third configuration of the rectangular module 46 and the housing 12, two sidewalls and the top portion of the rectangular module 46 are formed of thermally conductive materials. The two sidewalls of the rectangular module 46 are in direct contact with the two sidewall portions of the housing 12, respectively. The top portion of the rectangular module 46 is in direct contact with the top case portion of the housing 12. In some embodiments, the rectangular module 46 is a transformer. The sidewalls and the top portion of the rectangular module 46 are occupied by the windings of the transformer. The windings on the sidewalls of the rectangular module 46 are in direct contact with the two sidewall portions of the housing 12, respectively. The windings on the top portion of the rectangular module 46 are in direct contact with the top case portion of the housing 12. Alternatively, the sidewalls of the rectangular module 46 are occupied by different portions of the magnetic core of the transformer. The top portion of the rectangular module 46 is occupied by the windings of the transformer. The different portions of the magnetic core are in direct contact with the two sidewall portions of the housing 12, respectively. The windings on the top portion of the rectangular module 46 are in direct contact with the top case portion of the housing 12. The transformer has a plurality of terminals formed on the bottom portion of the transformer. The plurality of terminals is connected to the rest of the power supply unit through the bottom case portion of the housing 12.

In a fourth configuration of the rectangular module 46 and the housing 12, two sidewalls and the bottom portion of the rectangular module 46 are formed of thermally conductive materials. The two sidewalls of the rectangular module 46 are in direct contact with the two sidewall portions of the housing 12, respectively. The bottom portion of the rectangular module 46 is in direct contact with the bottom case portion of the housing 12. In some embodiments, the rectangular module 46 is a transformer. The sidewalls and the bottom portion of the rectangular module 46 are occupied by the windings of the transformer. The windings on the sidewalls of the rectangular module 46 are in direct contact with the two sidewall portions of the housing 12, respectively. The windings on the bottom portion of the rectangular module 46 are in direct contact with the bottom case portion of the housing 12. Alternatively, the sidewalls of the rectangular module 46 are occupied by different portions of the magnetic core of the transformer. The bottom portion of the rectangular module 46 is occupied by the windings of the transformer. The different portions of the magnetic core are in direct contact with the two sidewall portions of the housing 12, respectively. The windings on the bottom portion of the rectangular module 46 are in direct contact with the bottom case portion of the housing 12. The transformer has a plurality of terminals formed on the top portion of the transformer. The plurality of terminals is connected to the rest of the power supply unit through the top case portion of the housing 12.

In a fifth configuration of the rectangular module 46 and the housing 12, two sidewalls, the bottom portion and the top portion of the rectangular module 46 are formed of thermally conductive materials. The two sidewalls of the rectangular module 46 are in direct contact with the two sidewall portions of the housing 12, respectively. The bottom portion of the rectangular module 46 is in direct contact with the bottom case portion of the housing 12. The top portion of the rectangular module 46 is in direct contact with the top case portion of the housing 12. In some embodiments, the rectangular module 46 is a transformer. The sidewalls, the bottom portion and the top portion of the rectangular module 46 are occupied by the windings of the transformer. The windings on the sidewalls of the rectangular module 46 are in direct contact with the two sidewall portions of the housing 12, respectively. The windings on the bottom portion of the rectangular module 46 are in direct contact with the bottom case portion of the housing 12. The windings on the top portion of the rectangular module 46 are in direct contact with the top case portion of the housing 12. Alternatively, the sidewalls of the rectangular module 46 are occupied by different portions of the magnetic core of the transformer. The bottom portion and the top portion of the rectangular module 46 is occupied by the windings of the transformer. The different portions of the magnetic core are in direct contact with the two sidewall portions of the housing 12, respectively. The windings on the bottom portion of the rectangular module 46 are in direct contact with the bottom case portion of the housing 12. The windings on the top portion of the rectangular module 46 are in direct contact with the top case portion of the housing 12.

In some embodiments, some heat-generation components such as power switches 40 are mounted on the sidewall portions of the housing 12. The thermal communication between the heat-generation components and the sidewall portions of the housing 12 is enhanced by a diffusion accelerator. Examples of diffusion accelerators include thermal interface material pads 48. Furthermore, a thermally-conductive adhesive is used to fill the empty space inside the housing 12. This material modifies the boundary conditions of the heat transfer diffusion equation, effectively increasing the diffusion coefficient. As a result, thermal energy flows more efficiently between the heat-generating components and the sidewall portions of housing 12.

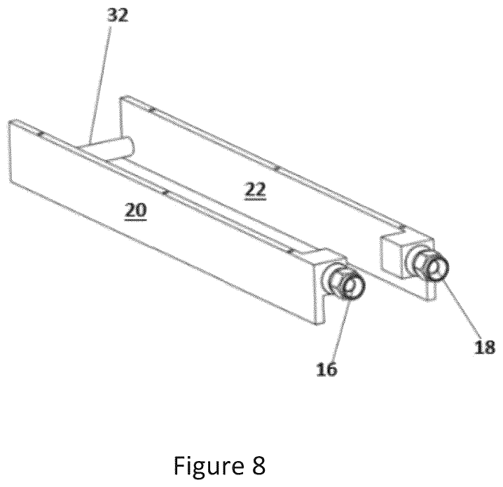

FIG. 8 illustrates a perspective view of the housing in accordance with various embodiments of the present disclosure. The first sidewall portion 20 and the second sidewall portion 22 have similar structures. The first sidewall portion 20 and the second sidewall portion 22 are made of a material having high electrical conductivity. Suitable examples include metals, such as aluminum and alloys thereof. Depending on design needs and different applications, suitable dielectric layers are formed on the first sidewall portion 20 and the second sidewall portion 22, respectively. As shown in FIG. 8, a connecting channel 32 connects the first sidewall portion 20 and the second sidewall portion 22. In operation, cooling fluid enters the housing inlet 16, passes through the first sidewall portion 20, the connecting channel 32 and the second sidewall portion 22 and exit at the housing outlet 18 after absorbing heat generated within the housing 12.

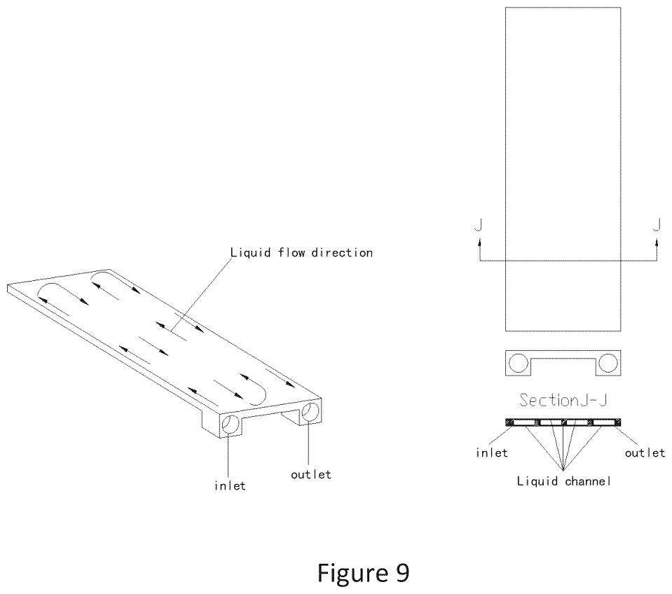

FIG. 9 illustrates another configuration of the liquid inlet and outlet in accordance with various embodiments of the present disclosure. At least one of the sidewall portions, the top case portion and the bottom case portion of the housing 12 can be implemented as the cold plate shown in FIG. 9. The cold plate comprises a meandering channel connected between an inlet and an outlet. As shown in FIG. 9, the inlet is adjacent to a leftmost corner of the cold plate. The outlet is adjacent to a rightmost corner of the cold plate. From the cross-section view of the cold plate, the cold plate includes four liquid channels.

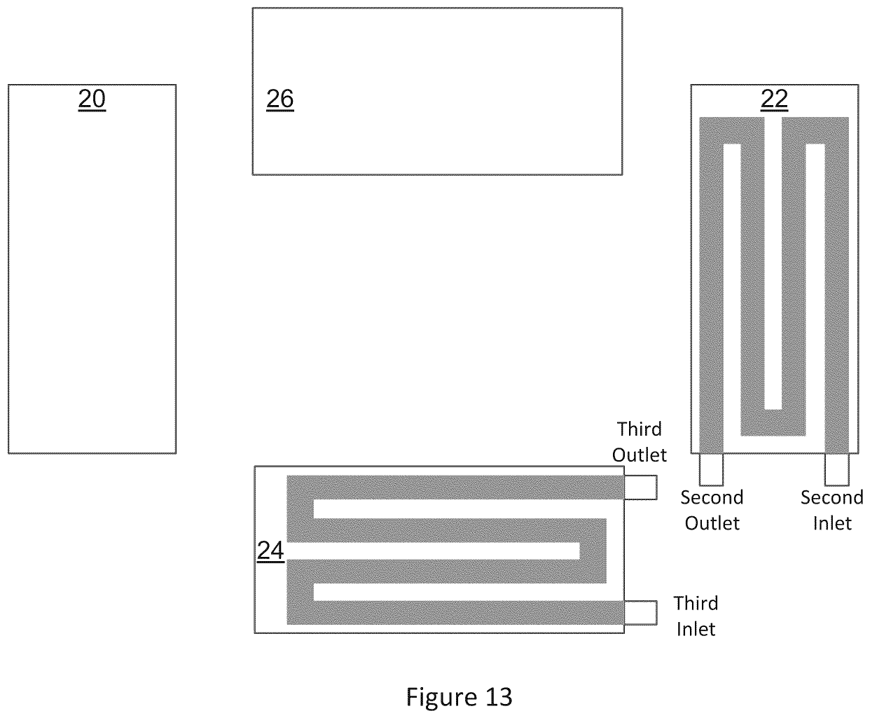

It should be noted that the inlet and outlet locations may be adjusted slightly to accommodate the adjacent outlet and inlets when each of the sidewall portions, the top case portion and the bottom case portion of the housing 12 includes both an outlet and an inlet (e.g., cooling implementations shown in FIGS. 13-18).

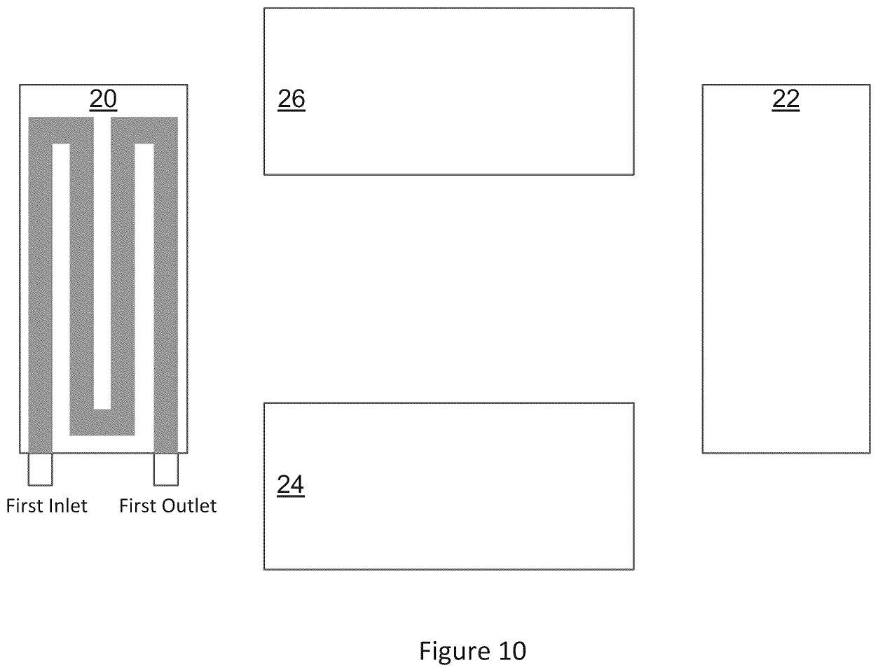

In FIGS. 10-18, in order to better illustrate the housing 12, the first sidewall portion 20 is rotated 90 degrees to the left around its bottom edge. Similarly, the second sidewall portion 22 is rotated 90 degrees to the right around its bottom edge. The bottom case portion 24 is rotated 90 degrees to the left relative to its center, while the top case portion 26 undergoes the same 90-degree leftward rotation with respect to its center.

FIG. 10 illustrates a first cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion 20. The first outlet is adjacent to a bottommost corner of the first sidewall portion 20. In operation, the first meandering channel is configured to provide thermal communication with the heat generation components. More particularly, the heat generation components (e.g., magnetic components, power switches and/or capacitors) and the sidewall portion 20 are arranged as shown in FIG. 7. The direct contact between the first sidewall portion 20 and the heat generation components facilitates efficient heat dissipation, thereby enhancing the thermal performance of the power supply unit.

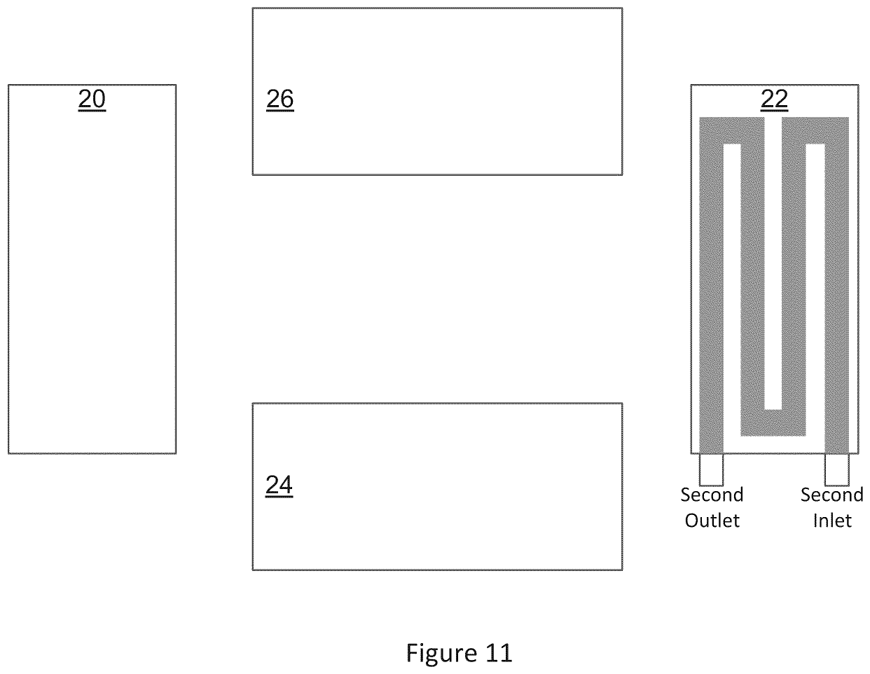

FIG. 11 illustrates a second cooling implementation of the housing in accordance with various embodiments of the present disclosure. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. In operation, the second meandering channel is configured to provide thermal communication with the heat generation components. More particularly, the heat generation components (e.g., magnetic components, power switches and/or capacitors) and the sidewall portion 22 are arranged as shown in FIG. 7. The direct contact between the sidewall portion 22 and the heat generation components facilitates efficient heat dissipation, thereby enhancing the thermal performance of the power supply unit.

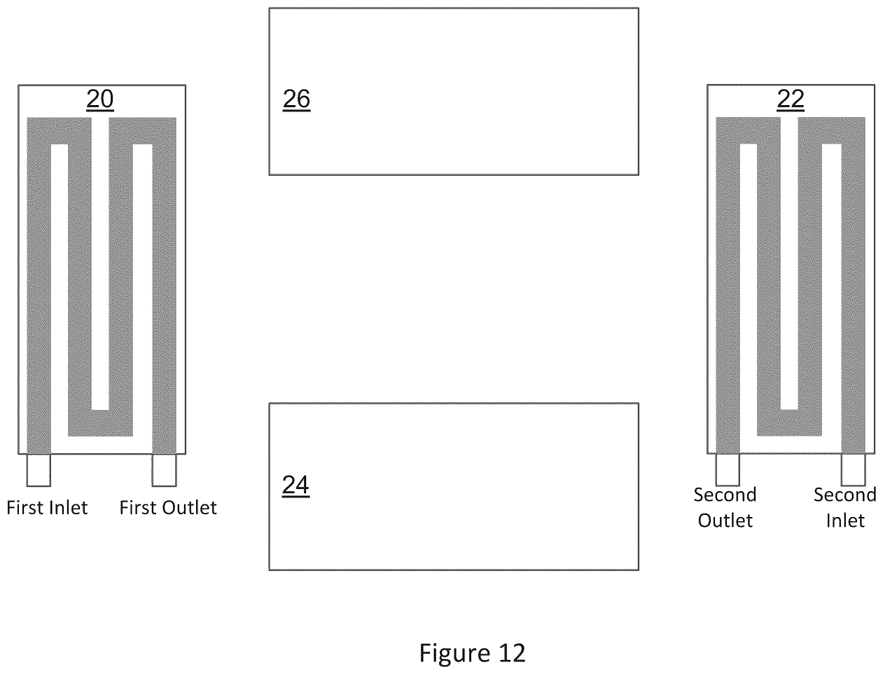

FIG. 12 illustrates a third cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion 20. The first outlet is adjacent to a bottommost corner of the first sidewall portion 20. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. The first meandering channel and the second meandering channel are configured to provide thermal communication with the heat generation components. More particularly, the heat generation components (e.g., magnetic components, power switches and/or capacitors), the first sidewall portion 20 and the second sidewall portion 22 are arranged as shown in FIG. 7. The direct contact between the sidewall portions 20, 22 and the heat generation components facilitates efficient heat dissipation, thereby enhancing the thermal performance of the power supply unit.

FIG. 13 illustrates a fourth cooling implementation of the housing in accordance with various embodiments of the present disclosure. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. The bottom case portion 24 comprises a third meandering channel connected between a third inlet and a third outlet. The third inlet is adjacent to a leftmost corner of the bottom case portion 24. The third outlet is adjacent to a rightmost corner of the bottom case portion 24. The second meandering channel and the third meandering channel are configured to provide thermal communication with the heat generation components. More particularly, the heat generation components (e.g., magnetic components, power switches and/or capacitors), the second sidewall portion 22 and the bottom case portion 24 are arranged as shown in FIG. 7. The direct contact between the second sidewall portion 22 and the heat generation components, and the direct contact between the bottom case portion 24 and the heat generation components facilitate efficient heat dissipation, thereby enhancing the thermal performance of the power supply unit.

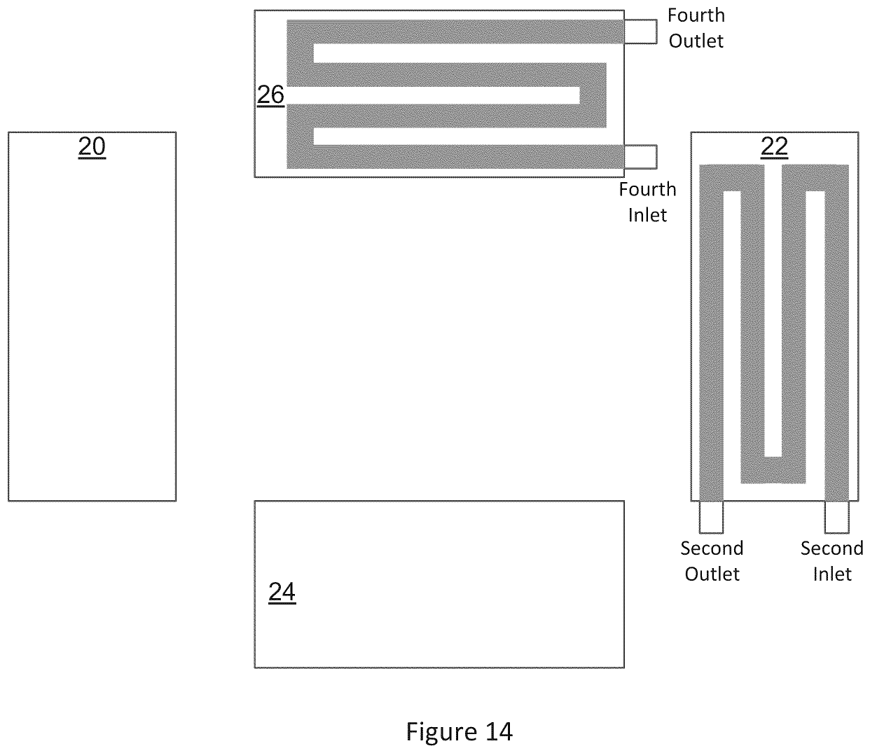

FIG. 14 illustrates a fifth cooling implementation of the housing in accordance with various embodiments of the present disclosure. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. The top case portion 26 comprises a fourth meandering channel connected between a fourth inlet and a fourth outlet. The fourth inlet is adjacent to a leftmost corner of the top case portion 26. The fourth outlet is adjacent to a rightmost corner of the top case portion 26. The second meandering channel and the fourth meandering channel are configured to provide thermal communication with the heat generation components. More particularly, the heat generation components (e.g., magnetic components, power switches and/or capacitors), the second sidewall portion 22 and the top case portion 26 are arranged as shown in FIG. 7. The direct contact between the second sidewall portion 22 and the heat generation components, and the direct contact between the top case portion 26 and the heat generation components facilitate efficient heat dissipation, thereby enhancing the thermal performance of the power supply unit.

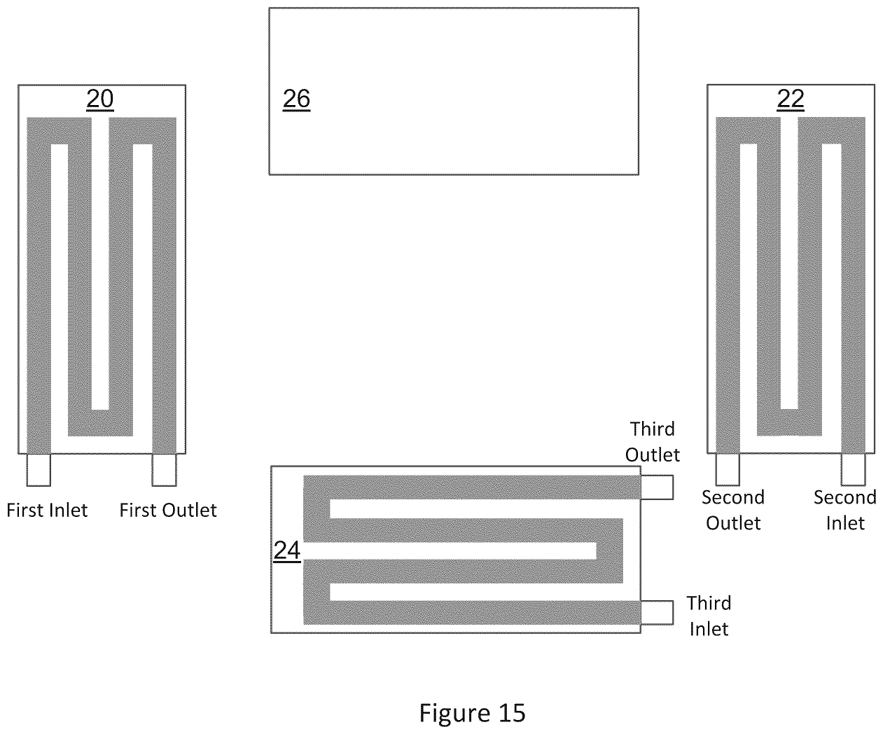

FIG. 15 illustrates a sixth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion 20. The first outlet is adjacent to a bottommost corner of the first sidewall portion 20. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. The bottom case portion 24 comprises a third meandering channel connected between a third inlet and a third outlet. The third inlet is adjacent to a leftmost corner of the bottom case portion 24. The third outlet is adjacent to a rightmost corner of the bottom case portion 24. The first meandering channel, the second meandering channel and the third meandering channel are configured to provide thermal communication with the heat generation components. More particularly, the heat generation components (e.g., magnetic components, power switches and/or capacitors), the first sidewall portion 20, the second sidewall portion 22 and the bottom case portion 24 are arranged as shown in FIG. 7. The direct contact between the first sidewall portion 20 and the heat generation components, the direct contact between the second sidewall portion 22 and the heat generation components, and the direct contact between the bottom case portion 24 and the heat generation components facilitate efficient heat dissipation, thereby enhancing the thermal performance of the power supply unit.

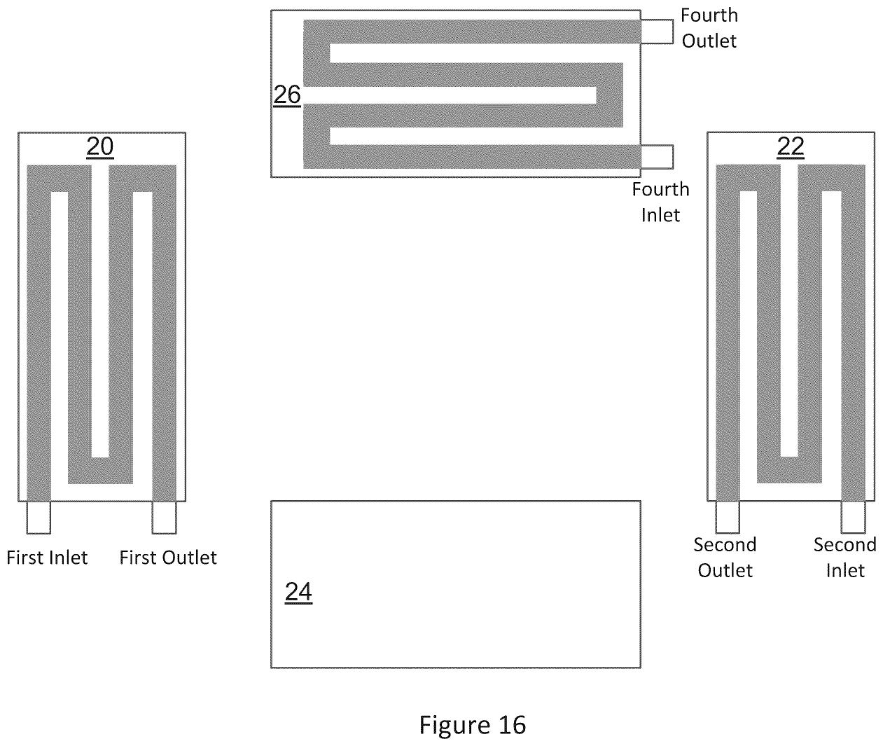

FIG. 16 illustrates a seventh cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion 20. The first outlet is adjacent to a bottommost corner of the first sidewall portion 20. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. The top case portion 26 comprises a fourth meandering channel connected between a fourth inlet and a fourth outlet. The fourth inlet is adjacent to a leftmost corner of the top case portion 26. The fourth outlet is adjacent to a rightmost corner of the top case portion 26. The first meandering channel, the second meandering channel and the fourth meandering channel are configured to provide thermal communication with the heat generation components. More particularly, the heat generation components (e.g., magnetic components, power switches and/or capacitors), the first sidewall portion 20, the second sidewall portion 22 and the top case portion 26 are arranged as shown in FIG. 7. The direct contact between the first sidewall portion 20 and the heat generation components, the direct contact between the second sidewall portion 22 and the heat generation components, and the direct contact between the top case portion 26 and the heat generation components facilitate efficient heat dissipation, thereby enhancing the thermal performance of the power supply unit.

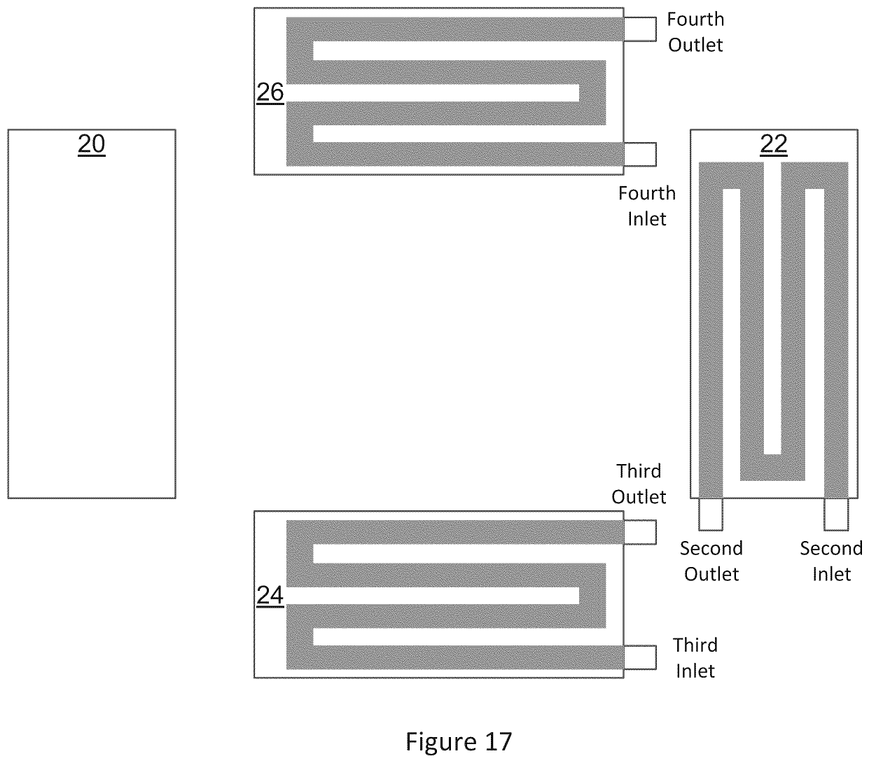

FIG. 17 illustrates an eighth cooling implementation of the housing in accordance with various embodiments of the present disclosure. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. The bottom case portion 24 comprises a third meandering channel connected between a third inlet and a third outlet. The third inlet is adjacent to a leftmost corner of the bottom case portion 24. The third outlet is adjacent to a rightmost corner of the bottom case portion 24. The top case portion 26 comprises a fourth meandering channel connected between a fourth inlet and a fourth outlet. The fourth inlet is adjacent to a leftmost corner of the top case portion 26. The fourth outlet is adjacent to a rightmost corner of the top case portion 26. The second meandering channel, the third meandering channel and the fourth meandering channel are configured to provide thermal communication with the heat generation components. More particularly, the heat generation components (e.g., magnetic components, power switches and/or capacitors), the second sidewall portion 22, the bottom case portion 24 and the top case portion 26 are arranged as shown in FIG. 7. The direct contact between the second sidewall portion 22 and the heat generation components, the direct contact between the bottom case portion 24 and the heat generation components, and the direct contact between the top case portion 26 and the heat generation components facilitate efficient heat dissipation, thereby enhancing the thermal performance of the power supply unit.

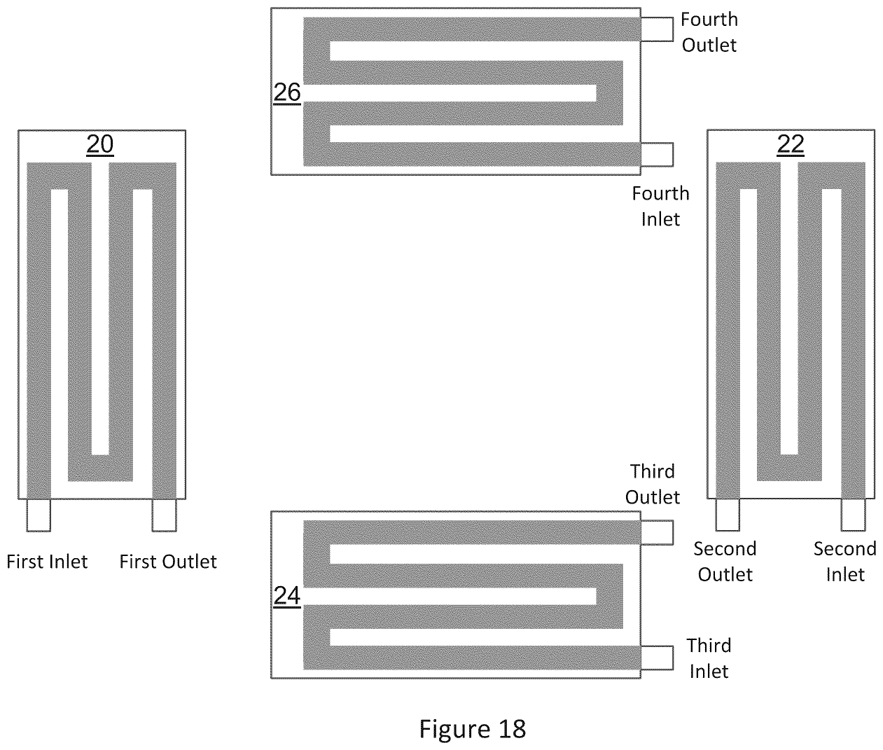

FIG. 18 illustrates a ninth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion 20. The first outlet is adjacent to a bottommost corner of the first sidewall portion 20. The second sidewall portion 22 comprises a second meandering channel connected between a second inlet and a second outlet. The second inlet is adjacent to a topmost corner of the second sidewall portion 22. The second outlet is adjacent to a bottommost corner of the second sidewall portion 22. The bottom case portion 24 comprises a third meandering channel connected between a third inlet and a third outlet. The third inlet is adjacent to a leftmost corner of the bottom case portion 24. The third outlet is adjacent to a rightmost corner of the bottom case portion 24. The top case portion 26 comprises a fourth meandering channel connected between a fourth inlet and a fourth outlet. The fourth inlet is adjacent to a leftmost corner of the top case portion 26. The fourth outlet is adjacent to a rightmost corner of the top case portion 26. The first meandering channel, the second meandering channel, the third meandering channel and the fourth meandering channel are configured to provide thermal communication with the heat generation components. More particularly, the heat generation components (e.g., magnetic components, power switches and/or capacitors), the first sidewall portion 20, the second sidewall portion 22, the bottom case portion 24 and the top case portion 26 are arranged as shown in FIG. 7. The direct contact between the first sidewall portion 20 and the heat generation components, the direct contact between the second sidewall portion 22 and the heat generation components, the direct contact between the bottom case portion 24 and the heat generation components, and the direct contact between the top case portion 26 and the heat generation components facilitate efficient heat dissipation, thereby enhancing the thermal performance of the power supply unit.

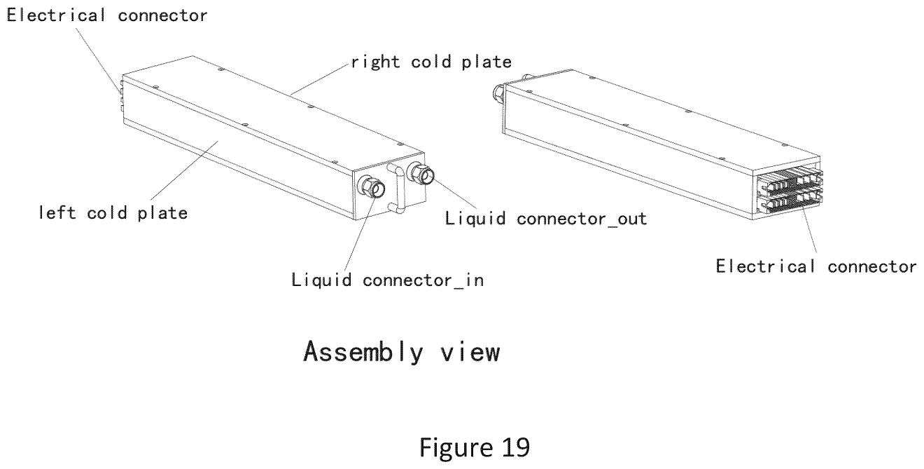

FIG. 19 illustrates a perspective view of another implementation of the power supply unit in accordance with various embodiments of the present disclosure. The power supply unit includes a housing. The housing comprises a first sidewall portion, a second sidewall portion, a bottom case portion, a top case portion, a front end and a rear end. As shown in FIG. 19, the first sidewall portion functions as a left cold plate. The second sidewall portion functions as a right cold plate. The internal structure of the power supply unit shown in FIG. 19 is similar to the power supply unit shown in FIG. 7, and hence is not discussed again herein.

As shown in FIG. 19, at the front end of the housing, there are the housing liquid inlet and the housing liquid outlet. The housing liquid inlet and the housing liquid outlet are connected to the left and right cold plates, respectively, allowing fluid flow between them. In operation, cooling fluid enters the housing liquid inlet and exits the housing liquid outlet after absorbing heat generated within the housing. An external pump supplies the energy necessary to drive the fluid flow from the housing liquid inlet, through the housing, and out the housing liquid outlet.

The power supply unit handles high levels of electrical current through connectors located at the rear end. These electrical connectors contain conductors that carry current, which results in ohmic heating as current flows through them. The heating is influenced by the current density, or the amount of current passing through a given area of the conductor. Since ohmic heating is directly related to current density, larger connectors are beneficial as they reduce current density by distributing the current over a larger surface area. This, in turn, minimizes heating and reduces ohmic losses.

The use of these larger connectors requires significant space at the rear end. In traditional air-cooled power supplies, much of this space is occupied by air vents, limiting the size of the connectors. However, since the power supply unit shown in FIG. 19 is liquid-cooled, the need for bulky air vents is eliminated, freeing up space for larger connectors. Additionally, to further optimize space, the housing liquid inlet and outlet are placed in the area adjacent to the front end, increasing the available contiguous area and allowing for even larger connectors at the rear end, thereby reducing ohmic heating losses.

As shown in FIG. 19, the liquid inlet and outlet are placed adjacent to the front end of the power supply unit. The connectors or power interfaces are placed adjacent to the rear end of the power supply unit. This configuration is able to separate the liquid connectors from the electrical connectors. Advantages of isolating the liquid connectors from the electrical connectors include the following: first, placing liquid and electrical connectors at opposite ends of the power supply unit physically separates them, preventing electrical damage caused by connector leakage. Second, positioning the electrical connectors at one end of the power supply unit allows for better use of space, enabling the use of larger connectors to meet higher current-carrying demands. Third, placing the electrical connectors at one end of the power supply unit makes hot-swapping easier, reducing the precision requirements for alignment. Fourth, placing the liquid inlet and outlet at the front end of the power supply unit makes liquid pipe installation easier, reducing the possibility of liquid leakage. Fifth, the liquid inlet and outlet at the front end of the housing make them easily accessible and such an easy access make the low-cost connection components to be used for connecting the liquid pipes and the liquid inlet and outlet.

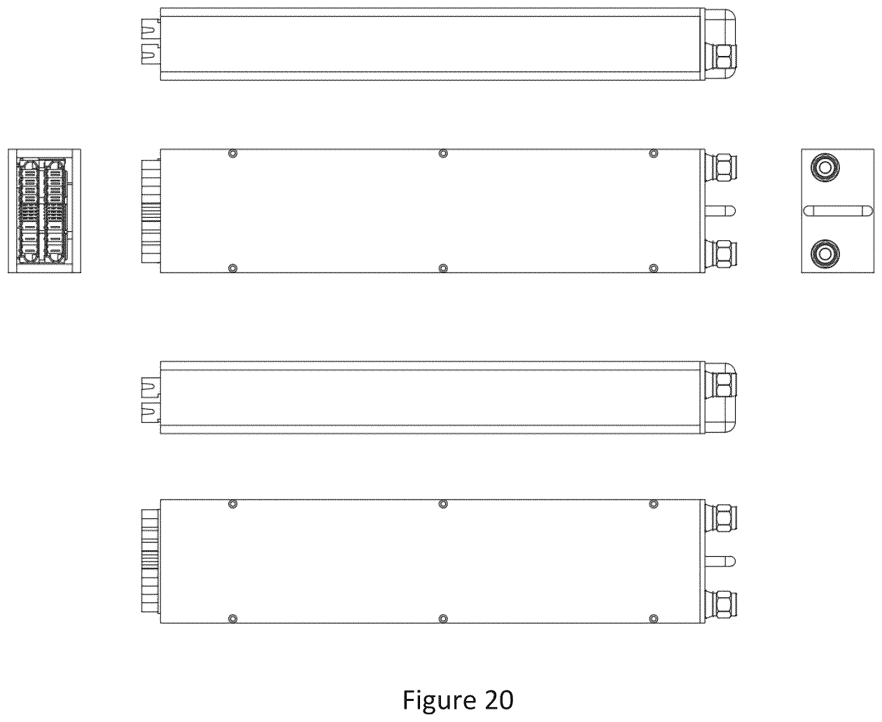

FIG. 20 illustrates a left-side view, a top side view, a right-side view and a bottom side view of the power supply unit shown in FIG. 19 in accordance with various embodiments of the present disclosure. FIG. 20 shows the electrical connectors are installed at the rear end of the power supply unit. The electrical connectors occupy the whole surface of the rear end of the housing. The liquid inlet and outlet are placed at the front end of the power supply unit.

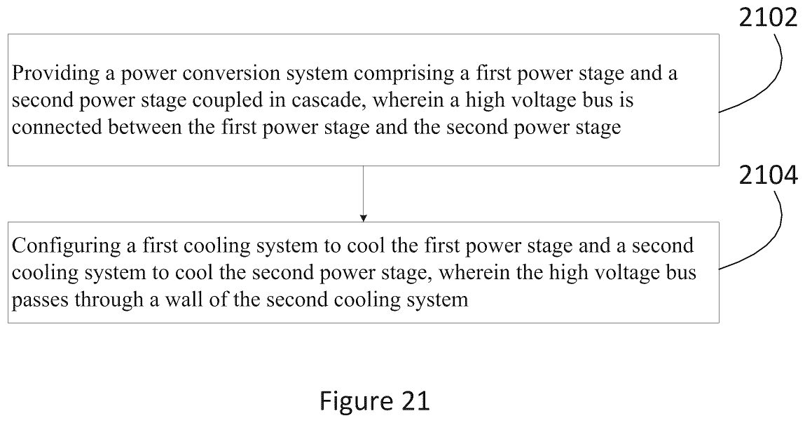

FIG. 21 illustrates a flow chart of a method for cooling the power conversion system shown in FIG. 1 in accordance with various embodiments of the present disclosure. This flowchart shown in FIG. 21 is merely an example, which should not unduly limit the scope of the claims. One of ordinary skill in the art would recognize many variations, alternatives, and modifications. For example, various steps illustrated in FIG. 21 may be added, removed, replaced, rearranged and repeated.

At step 2102, a power conversion system is provided. The power conversion system comprises a first power stage and a second power stage connected in cascade. A high voltage bus is connected between the first power stage and the second power stage.

At step 2104, a first cooling system is configured to cool the first power stage and a second cooling system is configured to cool the second power stage. The high voltage bus passes through a wall of the second cooling system.

The method further comprises configuring the first power stage to convert a three-phase ac source into a dc voltage of about 400 V on the high voltage bus, wherein the first power stage is a three-phase buck-type power factor correction rectifier.

The method further comprises controlling the first power stage such that the second power stage is configured to operate at a predetermined duty cycle, wherein the first power stage is a three-phase buck-type power factor correction rectifier, and the second power stage is an LLC resonant converter.

The method further comprises configuring the three-phase buck-type power factor correction rectifier to operate: in a linear mode in which at least one power switch of the three-phase buck-type power factor correction rectifier is driven by an adjustable gate drive voltage so that an output voltage of the three-phase buck-type power factor correction rectifier is adjusted, in a PWM mode in which a duty cycle of the three-phase buck-type power factor correction rectifier is adjusted so that the output voltage of the three-phase buck-type power factor correction rectifier is adjusted, and in a hybrid mode in which the linear mode and the PWM mode are applied to the three-phase buck-type power factor correction rectifier so that the output voltage of the three-phase buck-type power factor correction rectifier is adjusted and thermal stress is alleviated.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure f the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system comprising:
a first power stage and a second power stage coupled in cascade between an ac source and a load;
a high voltage bus connected between the first power stage and the second power stage;
a first cooling apparatus configured to cool the first power stage; and
a second cooling apparatus configured to cool the second power stage, wherein the high voltage bus passes through a wall of the second cooling apparatus.

2. The system of claim 1, wherein:
the second power stage comprises a power supply unit, wherein the power supply unit is connected to the high voltage bus through a first interface, and the power supply unit is connected to the load through a second interface; and
the power supply unit is placed inside a housing comprising a front side portion, a rear side portion, a first sidewall portion, a second sidewall portion, a bottom case portion and a top case portion, and wherein:
at least one of the first sidewall portion, the second sidewall portion, the bottom case portion and the top case portion comprises a channel through which coolant flows through to cool heat generation components of the power supply unit;
a liquid inlet and a liquid output are placed adjacent to the front side portion of the housing; and
the first interface and the second interface are placed adjacent to the rear side portion of the housing.

3. The system of claim 1, wherein:
the ac source is a three-phase ac source;
the first power stage is a three-phase buck-type power factor correction rectifier, and wherein the three-phase buck-type power factor correction rectifier is configured to convert the three-phase ac source into a dc voltage in a range from about 360 V to about 400 V on the high voltage bus; and
the second power stage is an inductor-inductor-capacitor (LLC) resonant converter.

4. The system of claim 1, wherein:
the first power stage is a three-phase buck-type power factor correction rectifier; and
the second power stage is an LLC resonant converter, and wherein the three-phase buck-type power factor correction rectifier is controlled such that the LLC resonant converter is configured to operate at a predetermined duty cycle.

5. The system of claim 1, wherein:
the first power stage is a three-phase buck-type power factor correction rectifier; and
the second power stage is an LLC resonant converter, and wherein the three-phase buck-type power factor correction rectifier is controlled such that the LLC resonant converter is configured to operate at a predetermined switching frequency.

6. The system of claim 1, wherein the first power stage is a three-phase buck-type power factor correction rectifier, and the three-phase buck-type power factor correction rectifier is configured to operate:
in a linear mode in which at least one power switch of the three-phase buck-type power factor correction rectifier is driven by an adjustable gate drive voltage so that an output voltage of the three-phase buck-type power factor correction rectifier is adjusted;
in a PWM mode in which a duty cycle of the three-phase buck-type power factor correction rectifier is adjusted so that the output voltage of the three-phase buck-type power factor correction rectifier is adjusted; and
in a hybrid mode in which the linear mode and the PWM mode are applied to the three-phase buck-type power factor correction rectifier in an alternating manner so that the output voltage of the three-phase buck-type power factor correction rectifier is adjusted and thermal stress is alleviated.

7. The system of claim 1, wherein:
the first power stage is a three-phase buck-type power factor correction rectifier, and wherein the three-phase buck-type power factor correction rectifier comprises:
a first filter capacitor connected between an output of a first phase of the three-phase ac source and a neutral point;
a second filter capacitor connected between an output of a second phase of the three-phase ac source and the neutral point;
a third filter capacitor connected between an output of a third phase of the three-phase ac source and the neutral point;
a first leg comprising a first diode, a first power switch, a second diode and a second power switch connected in series between a first voltage bus and a second voltage bus, wherein a common node of the first power switch and the second diode is connected to the first phase of the three-phase ac source;
a second leg comprising a third diode, a third power switch, a fourth diode and a fourth power switch connected in series between the first voltage bus and the second voltage bus, wherein a common node of the third power switch and the fourth diode is connected to the second phase of the three-phase ac source;
a third leg comprising a fifth diode, a fifth power switch, a sixth diode and a sixth power switch connected in series between the first voltage bus and the second voltage bus, wherein a common node of the fifth power switch and the sixth diode is connected to the third phase of the three-phase ac source;
an inductor connected between the first voltage bus and the high voltage bus; and
an output capacitor connected between the high voltage bus and the second voltage bus; and
the second power stage is an LLC resonant converter, and wherein the LLC resonant converter comprises:
a primary switch network comprising:
a first primary switch and a second primary switch connected in series between the high voltage bus and a primary ground; and
a third primary switch and a fourth primary switch connected in series between the high voltage bus and the primary ground;
a resonant tank comprising a resonant capacitor and a resonant inductor connected in series;
a secondary switch network comprising:
a first secondary switch and a second secondary switch connected in series between an output voltage bus and a secondary ground; and
a third secondary switch and a fourth secondary switch connected in series between the output voltage bus and the secondary ground;
a capacitor connected between the output voltage bus and the secondary ground; and
a transformer comprising a primary winding and a secondary winding, wherein:
a first terminal of the primary winding is connected to a common node of the first primary switch and the second primary switch through the resonant tank;
a second terminal of the primary winding is connected to a common node of the third primary switch and the fourth primary switch;
a first terminal of the secondary winding is connected to a common node of the first secondary switch and the second secondary switch; and
a second terminal of the secondary winding is connected to a common node of the third secondary switch and the fourth secondary switch.

8. The system of claim 7, wherein:
the output capacitor comprises an electrolytic capacitor.

9. The system of claim 1, wherein:
a voltage on the high voltage bus is in a range from about 360 V to about 400 V; and
a cooling capacity of the second cooling apparatus is greater than a cooling capacity of the first cooling apparatus.

10. The system of claim 1, wherein:
the first cooling apparatus is configured to utilize air to dissipate heat generated by the first power stage; and
the second cooling apparatus is configured to utilize liquid to dissipate heat generated by the second power stage, and wherein the second cooling apparatus comprises a tank configured to hold a coolant, and wherein the second power stage is sealed inside the tank.

11. The system of claim 1, wherein:
the second power stage comprises a power supply unit comprising a plurality of heat generation components; and
the power supply unit is placed inside a housing comprising a front side portion, a rear side portion, a first sidewall portion, a second sidewall portion, a bottom case portion and a top case portion, and wherein:
at least one of the first sidewall portion, the second sidewall portion, the bottom case portion and the top case portion comprises a channel through which coolant flows through to cool the heat generation components of the power supply unit;
at least one of the heat generation components is a rectangular module; and
at least one side of the at least one of the heat generation components is in direct contact with the at least one of the first sidewall portion, the second sidewall portion, the bottom case portion and the top case portion.

12. The system of claim 1, wherein:
the second power stage comprises a power supply unit comprising a plurality of heat generation components; and
the power supply unit is placed inside a housing comprising a front side portion, a rear side portion, a first sidewall portion, a second sidewall portion, a bottom case portion and a top case portion, and wherein:
the first sidewall portion comprises a first meandering channel through which coolant flows through to cool the heat generation components of the power supply unit;
the second sidewall portion comprises a second meandering channel through which coolant flows through to cool the heat generation components of the power supply unit;
at least one of the bottom case portion and the top case portion comprises a third meandering channel through which coolant flows through to cool the heat generation components of the power supply unit;
the heat generation components comprise a transformer packaged in a rectangular module designed to fit within the housing;
a first sidewall of the rectangular module is in direct contact with the first sidewall portion of the housing;
a second sidewall of the rectangular module is in direct contact with the second sidewall portion of the housing; and
at least one of a top surface and a bottom surface of the rectangular module is in direct contact with the at least one of the bottom case portion and the top case portion of the housing.

13. A method comprising:
providing a power conversion system comprising a first power stage and a second power stage connected in cascade, wherein a high voltage bus is connected between the first power stage and the second power stage; and
configuring a first cooling system to cool the first power stage and a second cooling system to cool the second power stage, wherein the high voltage bus passes through a wall of the second cooling system.

14. The method of claim 13, further comprising:
configuring the first power stage to convert a three-phase ac source into a dc voltage in a range from about 360 V to about 400 V on the high voltage bus, wherein the first power stage is a three-phase buck-type power factor correction rectifier.

15. The method of claim 13, further comprising:
controlling the first power stage such that the second power stage is configured to operate at a predetermined duty cycle, wherein:
the first power stage is a three-phase buck-type power factor correction rectifier; and
the second power stage is an LLC resonant converter.

16. The method of claim 15, further comprising:
configuring the three-phase buck-type power factor correction rectifier to operate:
in a linear mode in which at least one power switch of the three-phase buck-type power factor correction rectifier is driven by an adjustable gate drive voltage so that an output voltage of the three-phase buck-type power factor correction rectifier is adjusted;
in a PWM mode in which a duty cycle of the three-phase buck-type power factor correction rectifier is adjusted so that the output voltage of the three-phase buck-type power factor correction rectifier is adjusted; and
in a hybrid mode in which the linear mode and the PWM mode are applied to the three-phase buck-type power factor correction rectifier in an alternating manner so that the output voltage of the three-phase buck-type power factor correction rectifier is adjusted and thermal stress is alleviated.

17. A system comprising:
a plurality of first power stages coupled between an ac source and a high voltage bus;
a plurality of second power stages coupled between the high voltage bus and a load;
a first cooling apparatus configured to cool the plurality of first power stages; and
a second cooling apparatus configured to cool the plurality of second power stages and the load, wherein the high voltage bus passes through a wall of the second cooling apparatus.

18. The system of claim 17, wherein:
the load comprises a plurality of processors;
the ac source is a three-phase ac source;
each first power stage of the plurality of first power stages is a three-phase buck-type power factor correction rectifier, wherein the three-phase buck-type power factor correction rectifier is configured to convert the three-phase ac source into a dc voltage in a range from about 360 V to about 400 V on the high voltage bus; and
each second power stage of the plurality of second power stages is an LLC resonant converter.

19. The system of claim 17, wherein:
the plurality of first power stages is in parallel and hot swappable.

20. The system of claim 17, wherein:
a cardinality of the plurality of first power stages is greater than a cardinality of the plurality of second power stages.
